(19) United States
(12) Patent Application Publication
(10) Pub. No.: US 2025/0354296 A1
(43) Pub. Date: Nov. 20, 2025

(54) METHOD AND APPARATUS FOR MANUFACTURING SILICON CARBIDE SINGLE CRYSTAL

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Soma SAKAKIBARA, Nisshin-shi (JP); Akiyoshi HORIAI, Nisshin-shi (JP)

(21) Appl. No.: 19/188,757

(22) Filed: Apr. 24, 2025

(30) Foreign Application Priority Data
May 14, 2024 (JP) 2024-078759

(51) Int. Cl. C30B 33/12; C23C 16/32; C23C 16/44; C23C 16/458; C23C 16/46; C23C 16/56; C30B 25/10; C30B 25/12; C30B 29/36

(52) U.S. Cl. CPC C30B 33/12; C23C 16/325; C23C 16/4412; C23C 16/4583; C23C 16/46; C23C 16/56; C30B 25/10; C30B 25/12; C30B 29/36

(57) ABSTRACT

In a method and an apparatus for manufacturing a silicon carbide single crystal by a gas supply technique, a raw material gas of silicon carbide is introduced into a heating vessel through a first gas inlet disposed below a seed crystal placed on a pedestal, and the silicon carbide single crystal is grown on the seed crystal by heating and decomposing the raw material gas by heating the heating vessel to 2000° C. or higher and supplying the decomposed raw material gas to the seed crystal. Further, a growth surface of the silicon carbide single crystal is locally etched by spraying an etching gas from a gas-blowing outlet portion of a second gas inlet while heating the heating vessel to 2000° C. or higher. The gas-blowing outlet portion of the second gas inlet is disposed at a position protruding more than the first gas inlet toward the pedestal.

### CROSS REFERENCE TO RELATED APPLICATION

The present application claims the benefit of priority from Japanese Patent Application No. 2024-078759 filed on May 14, 2024. The entire disclosures of the above application are incorporated herein by reference.

### TECHNICAL FIELD

The present disclosure relates to a method and an apparatus for manufacturing a silicon carbide (hereinafter referred to as SiC) single crystal.

### BACKGROUND

As a method for manufacturing a SiC single crystal, a gas growth method has been known. In the gas growth method, a SiC raw material gas is supplied to a growth surface of a seed crystal made of a SiC single crystal so as to grow the SiC single crystal on the seed crystal. In the gas growth method, in addition to the SiC raw material gas, a dopant gas, such as nitrogen (N₂), which serves as a dopant for adjusting the resistivity of the crystal, is also introduced to manufacture the SiC single crystal.

### SUMMARY

The present disclosure describes a method and an apparatus for manufacturing a silicon carbide single crystal by a gas supply technique in which a silicon carbide raw material gas is supplied to grow a silicon carbide single crystal on a seed crystal. According to an aspect, the raw material gas of silicon carbide is introduced into a heating vessel through a first gas inlet disposed below the seed crystal placed on a pedestal, and the silicon carbide single crystal is grown on the seed crystal by heating and decomposing the raw material gas by heating the heating vessel to 2000° C. or higher and supplying the decomposed raw material gas to the seed crystal. Further, a growth surface of the silicon carbide single crystal is locally etched so as to reduce a height difference by performing at least one of (i) introducing a carrier gas, which serves as an etching gas, from the first gas inlet or (ii) spraying an etching gas from a gas-blowing outlet portion of a second gas inlet, while heating the heating vessel to 2000° C. or higher, the gas-blowing outlet portion of the second gas inlet being disposed at a position protruding more than the first gas inlet toward the pedestal.

### BRIEF DESCRIPTION OF DRAWINGS

Objects, features and advantages of the present disclosure will become more apparent from the following detailed description made with reference to the accompanying drawings, in which:

FIG. 1 is a cross-sectional view of a SiC single crystal manufacturing apparatus according to a first embodiment;

FIG. 2A is a diagram showing the state of a growth surface of a SiC single crystal before an etching gas is introduced;

FIG. 2B is a diagram showing the state of the growth surface of the SiC single crystal when one hour elapsed after the introduction of the etching gas;

FIG. 3 is a diagram showing the relationship between a H₂ flow rate and an etching amount per hour at a center position of the growth surface of the SiC single crystal;

FIG. 4 is a cross-sectional view of a SiC single crystal manufacturing apparatus according to a second embodiment; and

FIG. 5 is a diagram illustrating a change in the position of a gas-blowing outlet portion.

### DETAILED DESCRIPTION

In a case where a SiC single crystal is manufactured by a gas growth method, if the in-plane temperature and gas distribution on a growth surface of the SiC single crystal are not adjusted appropriately, the growth surface will have a concave or convex shape, resulting in large height differences on the growth surface. Furthermore, the internal stress of the SiC single crystal is likely to be increased, which causes crystal cracks.

As a technique for solving such drawbacks, a related art has proposed to use a reaction vessel provided with a diameter-narrowed part and to control a gas flow so that a SiC raw material gas is sprayed in a concentrated manner onto the center of the growth surface of the SiC single crystal. Also, it has been proposed to control the shape of the SiC single crystal by optimizing structures of components on a periphery of the SiC single crystal, surrounding the periphery of the growth surface with a thermal insulation member, and adjusting the temperature distribution on the growth surface.

However, even if the variation in growth distribution of the SiC single crystal is small, when the SiC single crystal is grown for a long period of time, the height differences on the growth surface increase cumulatively with time. However, it is difficult to solve this drawback by the technique of controlling the flow of gas sprayed onto the growth surface of the SiC single crystal or the technique of adjusting the temperature distribution on the growth surface by optimizing the structures of the components on the periphery of the SiC single crystal. Further, such techniques are likely to hinder the manufacturing of long SiC single crystals.

The present disclosure provides a method and an apparatus for manufacturing a SiC single crystal which has a growth surface with an enhanced shape.

According to an aspect of the present disclosure, a method for manufacturing a silicon carbide single crystal is implemented by a gas supply technique in which a raw material gas of silicon carbide is supplied to grow a silicon carbide single crystal on a seed crystal, and the method includes: placing the seed crystal on a pedestal disposed in a heating vessel that provides a hollow growth space for growing the silicon carbide single crystal; introducing the raw material gas into the heating vessel through a first gas inlet disposed below the seed crystal; growing the silicon carbide single crystal by heating and decomposing the raw material gas by heating the heating vessel to 2000° C. or higher and supplying the decomposed raw material gas to the seed crystal; and etching by performing at least one of (i) introducing a carrier gas, which serves as an etching gas, from the first gas inlet or (ii) spraying an etching gas from a gas-blowing outlet portion of a second gas inlet to locally etch a growth surface so as to reduce a height difference in the growth surface, while heating the heating vessel to 2000° C. or higher, the gas-blowing outlet portion of the second gas inlet being disposed at a position protruding more than the first gas inlet toward the pedestal.

In the method described above, the growth surface of the SiC single crystal is locally etched by spraying the etching gas onto the growth surface of the SiC single crystal. As such, it is possible to control the protrusion amount of the growth surface of the SiC single crystal to be small. For example, the growth surface can be preferably controlled to a flat surface. Therefore, it is possible to enhance the shape of the growth surface of the SiC single crystal.

According to an aspect of the present disclosure, an apparatus is for manufacturing a silicon carbide single crystal by a gas supply method in which a raw material gas of silicon carbide is supplied to grow a silicon carbide single crystal on a seed crystal, and the apparatus includes: a first gas inlet disposed to supply the raw material gas from a position below the seed crystal; a heating vessel providing a hollow growth space in which the raw material gas is heated and decomposed to grow the silicon carbide single crystal; a thermal insulation member arranged on a periphery of the heating vessel; a pedestal disposed in the heating vessel and on which the seed crystal is placed; a vacuum vessel in which the heating vessel, the thermal insulation member and the pedestal are accommodated; a heating device disposed to heat the heating vessel; a gas exhaust port disposed to exhaust an exhaust gas containing an unreacted gas of the raw material gas supplied to the seed crystal to an outside of the vacuum vessel from the growth space; and a second gas inlet having a gas-blowing outlet portion protruding more than the first gas inlet toward the pedestal to spray an etching gas to a growth surface of the silicon carbide single crystal.

In the apparatus described above, the second gas inlet is provided for the exclusive use of introducing the etching gas, and it is possible to locally etch the growth surface of the SiC single crystal. As such, it is possible to control the protrusion amount of the growth surface of the SiC single crystal to be small. For example, the growth surface can be preferably controlled to a flat surface. Therefore, it is possible to enhance the shape of the growth surface of the SiC single crystal.

Hereinafter, embodiments of the present disclosure will be described with reference to the drawings. In the following descriptions, the same or equivalent parts are denoted by the same reference numerals throughout the embodiments.

### First Embodiment

A SiC single crystal manufacturing apparatus according to a first embodiment is used to grow a SiC single crystal to be long by a gas supply method, thereby to manufacture a SiC single crystal ingot. This SiC single crystal manufacturing apparatus realizes a method for manufacturing a SiC single crystal, which can enhance the shape of a growth surface of the SiC single crystal.

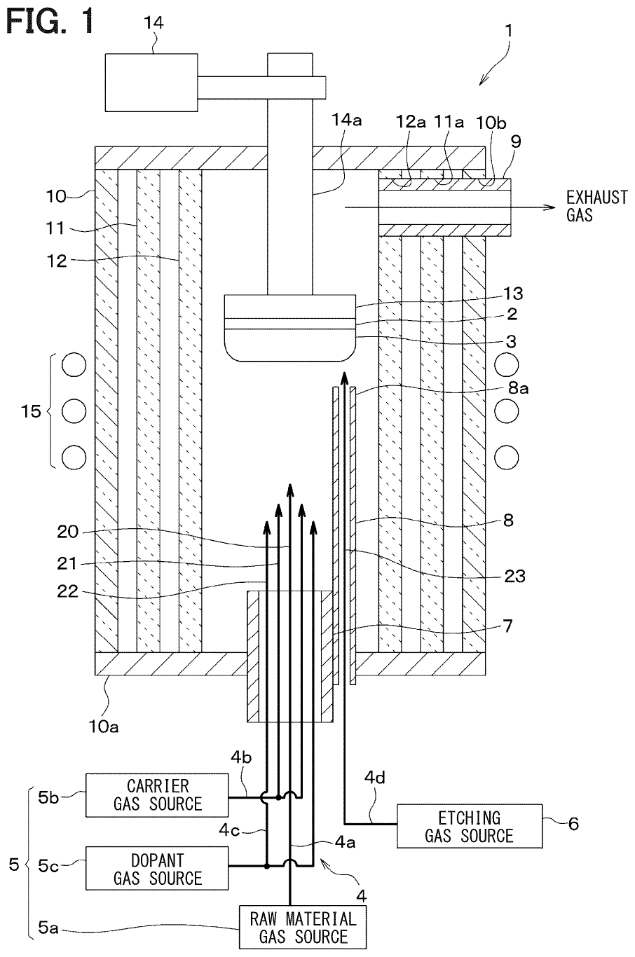

First, a SiC single crystal manufacturing apparatus 1 according to the present embodiment will be described with reference to FIG. 1. The SiC single crystal manufacturing apparatus 1 is installed such that an up and down direction in FIG. 1 is oriented in the vertical direction. The SiC single crystal manufacturing apparatus 1 supplies a SiC raw material gas to a surface of a seed crystal 2 composed of a SiC single crystal substrate to grow a SiC single crystal 3 on the surface of the seed crystal 2. Specifically, the SiC single crystal manufacturing apparatus 1 includes a gas supply unit 4, various supply gas sources 5, an etching gas source 6, first and second gas inlets 7 and 8, a gas exhaust port 9, a vacuum vessel 10, a thermal insulation member 11, a heating vessel 12, a pedestal 13, a rotary pull-up mechanism 14, and a heating device 15.

The gas supply unit 4 is provided at a lower part of the SiC single crystal manufacturing apparatus 1. The gas supply unit 4 introduces a raw material gas 20 containing various gases serving as a SiC raw material, a carrier gas 21 and a dopant gas 22 from various supply gas sources 5 to the inside of the SiC single crystal manufacturing apparatus 1. In addition, the gas supply unit 4 also introduces an etching gas 23 to the inside of the SiC single crystal manufacturing apparatus 1.

The gas supply unit 4 includes a raw material gas supply portion 4a that supplies the raw material gas 20, a carrier gas supply portion 4b that supplies the carrier gas 21, a dopant gas supply portion 4c that supplies the dopant gas 22, and an etching gas supply portion 4d that supplies the etching gas 23. Although not shown in detail, each of the gas supply portions 4a to 4d is provided by a component that forms a supply path. The raw material gas supply portion 4a introduces the raw material gas 20 from a raw material gas source 5a, which will be described later, into the SiC single crystal manufacturing apparatus 1. The carrier gas supply portion 4b introduces the carrier gas 21 from a carrier gas source 5b, which will be described later, into the SiC single crystal manufacturing apparatus 1. The dopant gas supply portion 4c introduces the dopant gas 22 from a dopant gas source 5c, which will be described later, into the SiC single crystal manufacturing apparatus 1. The etching gas supply portion 4d introduces the etching gas 23 from the etching gas source 6, which will be described later, into the SiC single crystal manufacturing apparatus 1.

The various supply gas sources 5 are configured to supply the gases including the SiC raw material gas into the SiC single crystal manufacturing apparatus 1 from a position below the seed crystal 2 placed on the pedestal 13. In the present embodiment, the various supply gas sources 5 include the raw material gas source 5a, the carrier gas source 5b, and the dopant gas source 5c. The first gas inlet 7 is provided at a bottom part 10a of the vacuum vessel 10, which will be described later. The various gases supplied from the various supply gas sources 5 are supplied to the first gas inlet 7 through the respective gas supply portions 4a to 4c, and are introduced into the SiC single crystal manufacturing apparatus 1 from the first gas inlet 7. For example, the first gas inlet 7 is provided by a cylindrical member, and is disposed such that a central axis of the cylindrical member coincides with the center of the seed crystal 2.

The raw material gas source 5a supplies the raw material gas 20, such as a SiC raw material gas containing silicon (Si) and carbon (C). The SiC raw material gas is, for example, a mixed gas of a silane-based gas such as silane and a hydrocarbon-based gas such as propane. The carrier gas source 5b supplies the carrier gas 21, such as an inert gas or H₂, which also serves as an etching gas. The inert gas is, for example, argon (Ar) gas or helium (He) gas. The dopant gas source 5c supplies the dopant gas 22 such as nitrogen (N₂) gas. Although not shown, each of the gas sources 5a to 5c includes a heating device for controlling the temperature of each supply gas, a flow rate control device for controlling the flow rate of each supply gas, and the like, so that the temperature and the flow rate of each supply gas can be controlled according to a growth state of the SiC single crystal 3.

Although N₂, which serves an n-type dopant, is illustrated as an example of the dopant gas 22, other n-type dopants may be used. A p-type dopant, such as trimethylaluminum (TMA), may be introduced.

The etching gas source 6 supplies the etching gas 23, such as H₂, to etch the growth surface of the SiC single crystal 3. In a case of the present embodiment, the etching gas supplied from the etching gas source 6 is introduced into the SiC single crystal manufacturing apparatus 1 from a position below the SiC single crystal 3, and is sprayed onto an outer edge of the SiC single crystal 3. The second gas inlet 8 is disposed at a position different from the first gas inlet 7 in the bottom part 10a of the vacuum vessel 10, which will be described later. The second gas inlet 8 protrudes higher than the first gas inlet 7. In other words, the second gas inlet 8 protrudes toward the pedestal 13 more than the first gas inlet 7. Therefore, a gas-blowing outlet portion 8a of the second gas inlet 8 is disposed closer to the SiC single crystal 3, making it easier to blow the etching gas 23 onto the growth surface of the SiC single crystal 3.

In a case of the present embodiment, the second gas inlet 8 has a cylindrical shape extending linearly in the vertical direction. The etching gas 23 passes through the inside of the second gas inlet 8 and is blown out from a position below the SiC single crystal 3. The central axis of the second gas inlet 8 is offset from the central axis of the first gas inlet 7, and the second gas inlet 8 is disposed on an outer periphery of the first gas inlet 7. Therefore, the flows of the various gases supplied from the first gas inlet 7 are less likely to be hindered by the second gas inlet 8. The second gas inlet 8 is positioned at a location corresponding to the outer edge of the pedestal 13. That is, the second gas inlet 8 is positioned to overlap with the pedestal 13 at least at a part when viewed from above. Therefore, the second gas inlet 8 enables to spray the etching gas locally onto the outer edge of the growth surface of the SiC single crystal 3.

The gas exhaust port 9 discharges unreacted gas of the raw material gas 20 after being supplied to the seed crystal 2, the carrier gas 21, the dopant gas 22, and the like to the outside of the SiC single crystal manufacturing apparatus 1 as exhaust gas.

The vacuum vessel 10 is made of quartz glass or the like and has a tubular shape providing a hollow portion therein. In the present embodiment, the vacuum vessel 10 has a cylindrical shape. The vacuum vessel 10 has such a structure that allows the raw material gas 20, the carrier gas 21, and the dopant gas 22 to be introduced therein and discharged therefrom. The vacuum vessel 10 accommodates other components of the SiC single crystal manufacturing apparatus 1 therein, and is configured to be able to reduce a pressure of an internal accommodation space by vacuum drawing. As described above, the first gas inlet 7 and the second gas inlet 8 are provided at the bottom part 10a of the vacuum vessel 10. The raw material gas 20, the carrier gas 21 and the dopant gas 22 are introduced into the SiC single crystal manufacturing apparatus 1 through the first gas inlet 7. The etching gas 23 is introduced into the SiC single crystal manufacturing apparatus 1 through the second gas inlet 8. Furthermore, a through hole 10b is formed in the upper portion of the vacuum vessel 10, specifically in the upper portion of the side wall of the vacuum vessel 10, and the gas exhaust port 9 is fitted into the through hole 10b.

The thermal insulation member 11 has a tubular shape providing a hollow portion therein. In a case of the present embodiment, the thermal insulation member 11 has a cylindrical shape, for example. The thermal insulation member 11 is disposed coaxially with the vacuum vessel 10. The thermal insulation member 11 has the cylindrical shape having a diameter smaller than a diameter of the vacuum vessel 10. The thermal insulation member 11 is disposed inside the vacuum vessel 10, to thereby restrict a heat transfer from a space inside the thermal insulation member 11 to the vacuum vessel 10. The thermal insulation member 11 is made of, for example, graphite. A surface of the thermal insulation member 11 may be coated with a high-melting point metal carbide such as tantalum carbide (TaC) or niobium carbide (NbC) so as to be less likely to be thermally etched. A through hole 11a is formed in an upper portion of the thermal insulation member11, specifically at a position corresponding to the through hole 10b of the vacuum vessel 10, and the gas exhaust port 9 is fitted into this through hole 11a.

The heating vessel 12 is a crucible serving as a reaction vessel forming a growth space for the SiC single crystal 3. The heating vessel 12 has a tubular shape providing a hollow portion therein. In the present embodiment, the heating vessel 12 has a cylindrical shape. The hollow portion of the heating vessel 12 forms a growth space to grow the SiC single crystal 3 on the surface of the seed crystal 2. The heating vessel 12 is made of, for example, graphite. A surface of the heating vessel 12 may be coated with a high-melting point metal carbide such as TaC or NbC so as to be less likely to be thermally etched. The heating vessel 12 is disposed so as to surround the pedestal 13. The exhaust gas, such as the unreacted gas in the raw material gas 20, is guided toward the gas exhaust port 9 through a space defined between an inner peripheral surface of the heating vessel 12 and outer peripheral surfaces of the seed crystal 2 and the pedestal 13. In the heating vessel 12, the SiC raw material gas in the raw material gas 20 from the raw material gas supply portion 4a is decomposed before the raw material gas 20 is introduced to the seed crystal 2. In addition, a through hole 12a is formed in an upper portion of the heating vessel 12, specifically at a position corresponding to the through hole 10b of the vacuum vessel 10 and the through hole 11a of the thermal insulation member 11. The gas exhaust port 9 is fitted into this through hole 12a.

The pedestal 13 is a member on which the seed crystal 2 is placed. The pedestal 13 has a first surface as a placement surface on which the seed crystal 2 having a disk shape is placed. The first surface of the pedestal 13 has, for example, a circular shape. The central axis of the pedestal 13 is disposed coaxially with the central axis of the heating vessel 12 and the central axis of the shaft 14a of the rotary pull-up mechanism 14, which will be described later. The pedestal 13 is made of, for example, graphite. A surface of the pedestal 13 may be coated with a high-melting point metal carbide such as TaC or NbC to be less likely to be thermally etched. The seed crystal 2 is attached to the first surface of the pedestal 13, the first surface facing the first gas inlet 7. The SiC single crystal 3 is grown on the surface of the seed crystal 2. The pedestal 13 is coupled to the shaft 14a on a second surface opposite to the first surface on which the seed crystal 2 is placed. The pedestal 13 is rotated with the rotation of the shaft 14a, and can be pulled upward as the shaft 14a is pulled upward.

The rotary pull-up mechanism 14 rotates and pulls up the pedestal 13 through the shaft 14a, which is provided by a pipe member or the like. In the present embodiment, the shaft 14a has a linear shape extending in the vertical direction. A first end of the shaft 14a is connected to the second surface of the pedestal 13 opposite to the first surface to which the seed crystal 2 is attached, and a second end of the shaft 14a is connected to a main body of the rotary pull-up mechanism 14. The shaft 14a is also made of, for example, graphite. A surface of the shaft 14a may be coated with a high-melting point metal carbide such as TaC or NbC to be less likely to be thermally etched. With the above configuration, the pedestal 13, the seed crystal 2, and the SiC single crystal 3 can be rotated and pulled up while the growth surface of the SiC single crystal 3 is controlled to have a suitable temperature distribution, and the temperature of the growth surface of the SiC single crystal 3 can be adjusted to a temperature suitable for growth in accordance with the growth of the SiC single crystal 3.

For example, the heating device 15 is provided by a heating coil such as an induction heating coil or a direct heating coil. The heating device 15 is disposed so as to surround the periphery of the vacuum vessel 10. In the present embodiment, the heating device 15 is provided by an induction heating coil, for example. In this case, the heating device 15 is configured as one part. Alternatively, the heating device 15 may be divided into multiple parts. In such a case, the heating device 15 is preferably configured so that the temperature of each target location can be controlled independently. For example, the parts of the heating device 15 can be disposed at a position corresponding to the lower portion of the heating vessel 12 and at a position corresponding to the pedestal 13. In this case, by the heating device 15, it is possible to independently and optimally perform control of the temperature of the lower portion of the heating vessel 12 so as to heat and decompose the SiC raw material gas and control of the temperature on the periphery of the pedestal 13, the seed crystal 2 and the SiC single crystal 3 to a suitable temperature for crystal growth.

The SiC single crystal manufacturing apparatus 1 has the configurations as described above. Next, a manufacturing method of the SiC single crystal 3 using the SiC single crystal manufacturing apparatus 1 according to the present embodiment will be described.

First, the seed crystal 2 is attached to the first surface of the pedestal 13. As the seed crystal 2, an off-substrate in which the surface opposite to the pedestal 13, that is, a growth surface of the SiC single crystal 3 has a predetermined off-angle of, for example 4° or 8°, with respect to a (000-1) C-plane is used. Next, the pedestal 13 and the seed crystal 2 are placed in the heating chamber 12. Then, the heating device 15 is controlled to provide a desired temperature distribution. In other words, the heating device 15 is controlled to provide the temperature distribution so that the SiC raw material gas contained in the raw material gas 20 is heated to be decomposed and supplied to the surface of the seed crystal 2, the SiC raw material gas is recrystallized on the surface of the seed crystal 2, and a sublimation rate is higher than a recrystallization rate in the heating vessel 12. In this manner, the temperature of the lower portion of the heating vessel 12 can be raised to a high temperature of 2000 degrees Celsius (° C.) or more, as well as the temperature of the surface of the seed crystal 2 can be made lower than that of the lower portion of the heating vessel 12 to be suitable for recrystallization of the SiC single crystal 3. For example, the inside of the heating vessel 12 is made to have a high temperature of 2000° C. or more. Preferably, at least a part of the inside of the heating vessel 12 is made to have a high temperature of 2500° C. or more. For example, the temperature of the lower portion of the heating vessel 12 is set to about 2800±100° C., and the temperature of the surface of the seed crystal is set to about 2500±100° C.

In addition, the raw material gas 20 containing the SiC raw material gas is introduced through the raw material gas supply portion 4a while the vacuum vessel 10 is set to a desired pressure. As a result, the raw material gas 20 is supplied to the seed crystal 2 as shown by the arrow in FIG. 1, and the SiC single crystal 3 is grown on the surface of the seed crystal 2 according to this gas supply.

Furthermore, the carrier gas 21 is introduced through the carrier gas supply portion 4b, and the dopant gas 22 is introduced through the dopant gas supply portion 4c. As a result, the carrier gas 21 and the dopant gas 22 are supplied inside the heating vessel 12, and the SiC single crystal 3 is doped with N contained in the dopant gas 22.

The rotary pull-up mechanism 14 rotates and pulls up the pedestal 13, the seed crystal 2 and the SiC single crystal 3 through the shaft 14a in accordance with the growth rate of the SiC single crystal 3. As a result, a height of the growth surface of the SiC single crystal 3 is kept substantially constant, and the temperature distribution of the growth surface can be controlled with high controllability.

As described above, even if a variation in growth distribution of the SiC single crystal 3 is small, the height differences of the growth surface will cumulatively increase over time when the SiC single crystal 3 is grown for a long period of time. This will hinder the increase in the length of the SiC single crystal 3. For this reason, the etching gas 23 or the carrier gas 21 containing H₂ is introduced while maintaining the temperature of 2000° C. or higher, such as the temperature during the crystal growth, so as to suppress the height differences in the growth surface of the SiC single crystal 3. In this case, there are two methods for introducing the etching gas 23.

(1) During the growth of the SiC single crystal 3, the supply of various gases such as the raw material gas 20 from the first gas inlet 7 is stopped to stop the growth of the SiC single crystal 3, and only the etching gas 23 is introduced. At this time, simultaneously with the etching gas 23 or instead of the etching gas 23, the carrier gas 21 containing H₂ may be introduced from the first gas inlet 7 to etch the center of the SiC single crystal 3.

(2) During the growth of the SiC single crystal 3, the supply of various gases such as the raw material gas 20 from the first gas inlet 7 is continued to grow the SiC single crystal 3, as well as the etching gas 23 is introduced. Any of the methods (1) and (2) can restrict the shape of the SiC single crystal 3 from becoming excessively convex during the growth. In addition, the methods (1) and (2) may be combined and both may be carried out.

The introduction of the etching gas 23 or the carrier gas 21 containing H₂ in the method (1) may be performed at any timing during the growth of the SiC single crystal 3, or may be performed at regular intervals. The regular intervals may be at constant intervals, or at intervals determined in accordance with the growth amount of the SiC single crystal 3, such as time intervals in which the time intervals for introducing the etching gas 23 become shorter as the growth amount increases.

For example, the SiC raw material in the unreacted gas may adhere to the gas exhaust port 9, and clog the gas exhaust port 9. Thus, it is preferable to measure in advance the time required for clogging the gas exhaust port 9 by an experiment or the like, and introduce the etching gas 23 or the carrier gas 21 containing H₂ at a timing shorter than the time required for clogging. In this way, the clogging of the gas exhaust port 9 due to adhesion of the SiC raw material can be suppressed, and it becomes possible to grow the SiC single crystal 3 longer.

When the SiC single crystal 3 grows, three-dimensional nuclei may be incorporated to the growth surface, and polycrystallization may occur starting from the three-dimensional nuclei. For this reason, it is preferable to introduce the etching gas 23 or the carrier gas 21 containing H₂ at a time interval shorter than the time interval from the incorporation of the three-dimensional nuclei to the polycrystallization so that the three-dimensional nuclei can be removed at a timing before the polycrystallization, even if the three-dimensional nuclei is incorporated,

If both the clogging of the gas exhaust port 9 and the incorporation of three-dimensional nuclei are taken into consideration, the etching gas 23 or the carrier gas 21 containing H₂ can be introduced before a shorter one of the time required till the gas exhaust port 9 is clogged or the time from the incorporation of the three-dimensional nuclei to the polycrystallization elapses. In addition, in a case where a device capable of monitoring the growth surface of the SiC single crystal 3 is provided, the etching gas 23 or the carrier gas 21 containing H₂ may be introduced at the timing when an occurrence of incorporation of the three-dimensional nuclei is detected.

In contrast, in the case where the etching gas 23 is introduced by the method (2), the timing to introduce the etching gas 23 may be set according to the gas supply conditions from the first gas inlet 7 and the temperature distribution on the growth surface of the SiC single crystal 3. In this case, it is preferable to make the temperature of the growth surface of the SiC single crystal 3 higher than that before the introduction of the etching gas 23. For example, it is controlled so that the temperature of the growth surface of the SiC single crystal 3 when the etching gas 23 is introduced is higher about 50 to 100° C. than that before the etching gas 23 is introduced. This allows etching to predominate. As a result, it is possible to restrict the growth surface of the SiC single crystal 3 from becoming excessively convex during the growth.

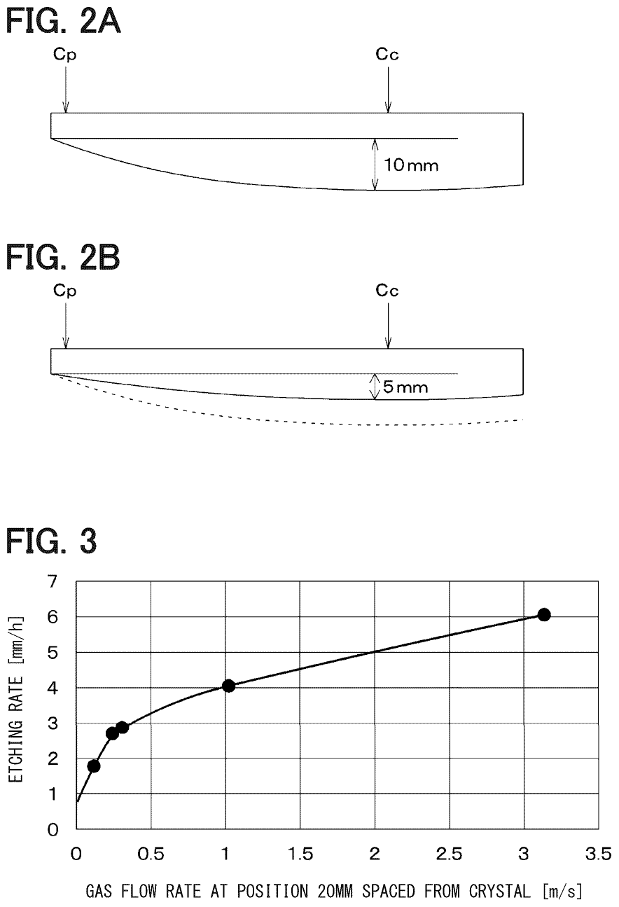

For example, a SiC single crystal 3 having a size from which a 6-inch wafer can be extracted was produced. In this case, as shown in FIG. 2A, the protrusion amount of the convex shape before the introduction of the etching gas 23, that is, the protrusion amount at a crystal center (Cc) relative to a crystal periphery (Cp), was 10 mm. In this case, the introduction of the etching gas 23 was started after the growth of the SiC single crystal 3 was stopped, and the protrusion amount of the convex shape after one hour from the start of the introduction of the etching gas 23 was checked. As a result, the protrusion amount was decreased to 5 mm, as shown in FIG. 2B. Note that FIG. 2B was an example in which only the carrier gas 21 containing H₂ was used, and therefore the center of the SiC single crystal 3 was etched. Further, in a case where the etching gas 23 is used, the outer periphery of the SiC single crystal 3 is locally etched.

In this manner, by introducing the etching gas 23 or the carrier gas 21 containing H₂, the height differences on the growth surface of the SiC single crystal 3 can be suppressed. After the growth is completed, if the heating vessel 12 is maintained at 2000° C. or higher and the growth surface of SiC single crystal 3 is flattened before the SiC single crystal 3 is cooled, it is possible to suppress crystal cracking due to stress caused when the SiC single crystal 3 is cooled.

The etching amount and etching time of the SiC single crystal 3 may be set according to a desired height difference of the growth surface. Specifically, it has been confirmed that the etching amount at the central position of the growth surface of the SiC single crystal 3 is proportional to the flow rate of the etching gas 23 or the carrier gas 21 containing H₂ and the etching time. For example, FIG. 3 shows a simulation result when H₂ is introduced as the etching gas 23, and indicates the relationship between the flow rate of H₂ as the etching gas 23 and the etching rate at the central position of the growth surface of the SiC single crystal. In this calculation, the surface temperature of the seed crystal 2 is set to 2500° C.

The etching rate is dependent on the gas flow rate in the vicinity of the crystal. For example, when the gas flow rate [m/s] in the vicinity of the SiC single crystal 3 is controlled to 2 m/s, it is possible to control the etching rate of the SiC crystal 3 to 5 mm/h. In this case, it is possible to etch the central portion of the SiC single crystal 3 by 5 mm for one hour. For this reason, the introducing time of the etching gas 23 or the carrier gas 21 containing H₂ and the etching time are set so that the protrusion amount after the etching becomes the desired amount based on the expected protrusion amount of the convex shape at the timing of introduction of the etching gas 23 or the carrier gas 21 containing H₂ and the etching amount at the central position of the growth surface of the SiC single crystal 3. As a result, it is possible to control the protrusion amount after the etching to a desired amount. For example, even if the central position of the growth surface of SiC single crystal 3 is protruded more than the outer edge, the protrusion amount can be controlled to be 5 mm or less, and preferably the protrusion amount can be controlled so that the growth surface becomes a flat surface.

As described above, the manufacturing apparatus for the SiC single crystal 3 according to the present embodiment is provided with the second gas inlet 8 exclusively for introducing the etching gas 23, thereby to enable localized etching of the growth surface of the SiC single crystal 3. Thus, it is possible to control the protrusion amount of the growth surface of the SiC single crystal 3 to be small, and preferably the growth surface can be controlled to be a flat surface. In this way, it is possible to enhance the shape of the growth surface of the SiC single crystal 3. As a result, it is possible to make the SiC single crystal 3 long.

### Second Embodiment

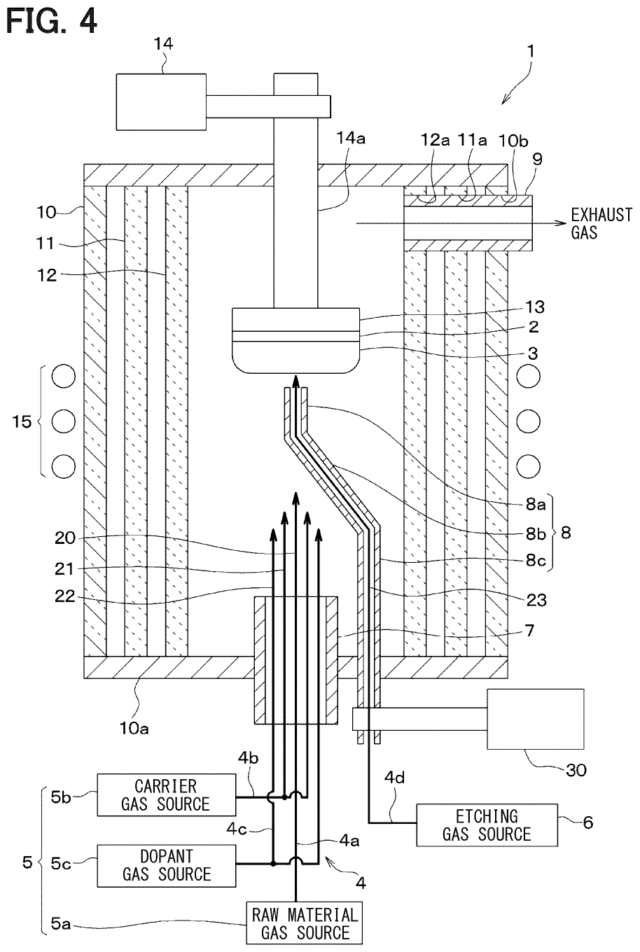

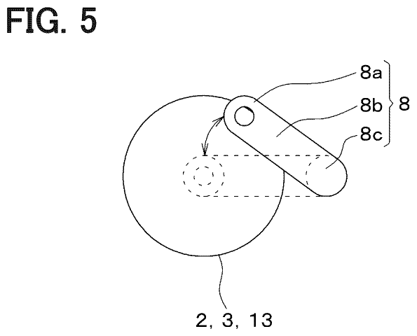

A second embodiment will be descried with reference to FIGS. 4 and 5. In the present embodiment, the configuration of the second gas inlet 8 is changed from that of the first embodiment. The other configurations of the present embodiment are similar to those of the first embodiment, and the portion different from the first embodiment will be mainly described hereinafter.

As shown in FIG. 4, in the present embodiment, the second gas inlet 8 is not straight, but has a bent portion 8b at an intermediate position in the vertical direction, so that the gas-blowing outlet portion 8a of the second gas inlet 8 is offset relative to a base portion 8c of the second gas inlet 8 located adjacent to the bottom part 10a of the vacuum vessel 10. In other words, the second gas inlet 8 has a structure in which the gas-blowing outlet portion 8a extending in the vertical direction and the base portion 8c extending in the vertical direction are connected through the bent portion 8b that is inclined with respect to the vertical direction. A rotation mechanism 30 is coupled to the base portion 8c, and the rotation mechanism 30 enables the base portion 8c to rotate. Specifically, the gas-blowing outlet portion 8a, the bent portion 8b, and the base portion 8c each have a cylindrical shape with a circular cross-section. The gas-blowing outlet portion 8a and the base portion 8c extend in the vertical direction, and the bent portion 8b is inclined with respect to the vertical direction. The base portion 8c is rotated by the rotation mechanism 30 about a line extending in the vertical direction as a central axis of rotation, whereby the bent portion 8b and the gas-blowing outlet portion 8a are also rotated. Since the gas-blowing outlet portion 8a is eccentric with respect to the base portion 8c due to the bent portion 8b being inclined relative to the vertical direction, the position of the gas-blowing outlet portion 8a changes so as to revolve around the base portion 8c when the base portion 8c is rotated, as shown in FIG. 5.

Therefore, it is possible to spray the etching gas 23 locally to a desired position on the growth surface of the SiC single crystal 3 by changing the position of the gas-blowing outlet portion 8a. As such, the etching gas 23 can be sprayed more precisely to a portion that protrudes more than other portions, making it possible to further flatten the growth surface of the SiC single crystal 3. Even if the gas-blowing outlet portion 8a is located at a position offset from the center position of the growth surface of the SiC single crystal 3, since the SiC single crystal 3 is rotated by the rotary pull-up mechanism 14, the etching gas 23 is sprayed over the entire area that is at the same distance from the center of the growth surface. Since the distribution of height differences within the growth surface is determined according to the distance from the central position of the growth surface, the etching gas 23 can be sprayed in the same manner over the entire equidistant area, and the etching can be performed uniformly.

### OTHER EMBODIMENTS

While the present disclosure has been described in accordance with the embodiments described above, the present disclosure is not limited to the embodiments described above and includes various modifications and equivalent modifications. Various combinations or forms as well as other combinations or forms including only one element, one or more elements, or fewer elements fall within the scope or the concept of the present disclosure.

In other words, the elements constituting the above-described embodiments are not necessarily essential, except in cases where they are particularly expressly stated as essential or where they are clearly considered essential in principle. When numerical values such as the number, amount, and range of elements are mentioned, the present disclosure is not limited to the specific numerical values unless otherwise specified as essential or obviously limited to the specific numerical values in principle. Similarly, in the case where the shape, the direction, the positional relationship, and/or the like of the constituent element(s) is specified, the present disclosure is not necessarily limited to the shape, the direction, the positional relationship, and/or the like unless the shape, the direction, the positional relationship, and/or the like is/are indicated as essential or is/are obviously essential in principle.

For example, in each of the embodiments described above, it has been illustrated that the second gas inlet 8 has the cylindrical shape with a circular cross section. However, the second gas inlet 8 may not have the cylindrical shape with a circular cross section. The example in which only one second gas inlet 8 is provided has been illustrated. Alternatively, two or more second gas inlets 8 may be provided. In such a case, it is preferable that the gas inlets are arranged at equal intervals in the circumferential direction around the first gas inlet 7. However, when the gas-blowing outlet portion 8a of the second gas inlet 8 is configured to be movable up to the central position of the growth surface of the SiC single crystal 3 as in the second embodiment, the gas-blowing outlet portions 8a may come into contact with each other. Therefore, it is preferable to control the rotation mechanism 30 so that the gas-blowing outlet portions 8a do not come into contact with each other. Alternatively, the eccentricity of the gas-blowing outlet portions 8a with respect to the base portions 8c may be adjusted so that the gas-blowing outlet portions 8a do not come into contact with each other.

In the first embodiment, the raw material gas 20, the carrier gas 21, and the dopant gas 22 are introduced from the first gas inlet 7. Alternatively, the raw material gas 20, the carrier gas 21 and the dopant gas 22 may be introduced from different inlet members or different openings. Moreover, the introduction of the carrier gas 21 is optional, and only the raw material gas 20 and the dopant gas 22 may be introduced.

In the first embodiment, the SiC single crystal manufacturing apparatus 1 has been described as an example of an up-flow method in which the raw material gas 20 is supplied to the growth surface of the SiC single crystal 3 and then passed through the outer peripheral surface of the SiC single crystal 3 or the side of the pedestal 13 upward to be discharged. However, the present disclosure is not limited to the above configuration, but a return flow system may be applied in which after the raw material gas 20 is supplied to the growth surface of the SiC single crystal 3, the raw material gas 20 is returned in the same direction as the supply direction again. In addition, a side-flow method may be employed in which the raw material gas 20 is supplied to the growth surface of the SiC single crystal 3 and then discharged toward the outer periphery of the heating vessel 12.

What is claimed is:

1. A method for manufacturing a silicon carbide single crystal by a gas supply technique in which a raw material gas of silicon carbide is supplied to grow a silicon carbide single crystal on a seed crystal, the method comprising:
placing the seed crystal on a pedestal disposed in a heating vessel that provides a hollow growth space for growing the silicon carbide single crystal;
introducing the raw material gas into the heating vessel through a first gas inlet disposed below the seed crystal;
growing the silicon carbide single crystal by heating and decomposing the raw material gas by heating the heating vessel to 2000° C. or higher and supplying the decomposed raw material gas to the seed crystal; and
etching by performing at least one of (i) introducing a carrier gas, which serves as an etching gas, from the first gas inlet or (ii) spraying an etching gas from a gas-blowing outlet portion of a second gas inlet to locally etch a growth surface so as to reduce a height difference in the growth surface, while heating the heating vessel to 2000° C. or higher, the gas-blowing outlet portion of the second gas inlet being disposed at a position protruding more than the first gas inlet toward the pedestal.

2. The method according to claim 1, wherein
in the etching, H₂ is sprayed locally to the growth surface as the etching gas.

3. The method according to claim 1, wherein
in the etching, the etching gas is introduced in a state where the introducing of the raw material gas is stopped.

4. The method according to claim 1, wherein
in the etching, the etching gas is introduced in a state where the introducing of the raw material gas is continued.

5. The method according to claim 4, wherein
in the etching, the etching gas is introduced periodically.

6. An apparatus for manufacturing a silicon carbide single crystal by a gas supply method in which a raw material gas of silicon carbide is supplied to grow a silicon carbide single crystal on a seed crystal, the apparatus comprising:
a first gas inlet disposed to supply the raw material gas from a position below the seed crystal;
a heating vessel providing a hollow growth space in which the raw material gas is heated and decomposed to grow the silicon carbide single crystal;
a thermal insulation member arranged on a periphery of the heating vessel;
a pedestal disposed in the heating vessel and on which the seed crystal is placed;
a vacuum vessel accommodating the heating vessel, the thermal insulation member and the pedestal therein;
a heating device disposed to heat the heating vessel;
a gas exhaust port disposed to exhaust an exhaust gas containing an unreacted gas of the raw material gas supplied to the seed crystal to an outside of the vacuum vessel from the growth space; and
a second gas inlet having a gas-blowing outlet portion protruding more than the first gas inlet toward the pedestal to spray an etching gas to a growth surface of the silicon carbide single crystal.

7. The apparatus according to claim 6, wherein
the pedestal has a first surface on which the seed crystal is placed, the first surface having a circular shape, and
the gas-blowing outlet portion of the second gas inlet is located at a position corresponding to an outer edge of the first surface of the pedestal to spray the etching gas to an outer edge portion of the growth surface.

8. The apparatus according to claim 6, wherein
the second gas inlet has a base portion and a bent portion,
the base portion is disposed at a position different from the first gas inlet in a bottom part of the vacuum vessel and extends in a vertical direction from the bottom part, and
the bent portion connects between the base portion and the gas-blowing outlet portion, and is inclined relative to the vertical direction so that the gas-blowing outlet portion is offset from the base portion,
the apparatus further comprising:
a rotation mechanism that rotates the base portion to change a position of the gas-blowing outlet portion.
